(19) United States
(12) Patent Application Publication
(10) Pub. No.: US 2006/0133036 A1
(43) Pub. Date: Jun. 22, 2006

(54) Heat dissipation assembly and method for cooling heat-generating components in an electrical device

(75) Inventor: Max W. Durney, San Francisco, CA (US)

Correspondence Address: David J. Brezner;Dorsey & Whitney LLP, Intellectual Property Department, 555 California Street, Suite 1000, San Francisco, CA, 94104-1513, US

(73) Assignee: INDUSTRIAL ORIGAMI, LLC, San Francisco, CA (US)

(21) Appl. No.: 11/282,308

(22) Filed: Nov. 18, 2005

Related U.S. Application Data
(60) Provisional application No. 60/629,845, filed on Nov. 18, 2004.

(51) Int. Cl. H05K 7/20

(52) U.S. Cl. 361/695; 361/688

(57) ABSTRACT

A heat dissipation structure suitable for use in electrical and electronic equipment enclosed in housings which equipment is fan cooled. The structure includes a partition array inside the housing formed to preferentially cool relatively high heat-generating electronic components mounted to a PCB board or the like. The structure advantageously includes partitions which narrow to a throat that accelerates the airflow past the heat-generating components for maximum heat transfer. A method of dissipating heat from the high heat-generating electronic components in an electronic device also is disclosed.

### CROSS-REFERENCES TO RELATED APPLICATIONS

This application claims priority to U.S. Provisional Patent Application No. 60/629,845 filed Nov. 18, 2004, entitled A HEAT DISSIPATION ASSEMBLY AND METHOD FOR COOLING HEAT-GENERATING COMPONENTS IN AN ELECTRICAL DEVICE, the entire contents of which is incorporated herein by this reference.

### TECHNICAL FIELD

The present invention relates, in general, to methods and apparatus for cooling heat-generating electrical components in electrical equipment, and more particularly, relates to fan cooling of heat-generating electronic components mounted on printed circuit boards or component-carrying cards or substrates.

### BACKGROUND ART

In recent years, decreases in the size of electronic components and increases in their speed have also been accompanied by increases in the heat generated by such components. Computer processors (CPUs) and power transistors are common offenders when it comes to the generation of excess heat. When such components are mounted to printed circuit boards, cards or component-carrying substrates, they also will typically be surrounded by a housing or enclosure which makes heat dissipation more difficult.

It is well known for such electrical and electronic equipment to be fan cooled, that is, for one or more fans to be used to blow air over or pull air through, the equipment housing in order to dissipate heat. That approach to cooling electronic apparatus has worked well until very recently when the increases in component speed have been accompanied by very substantial increases in heat generation. Some lap top computers, for example, are now getting so hot in localized areas of the electronic circuitry that they can be dangerous, or at least uncomfortable to literally place on a user's lap.

The heat dissipation issues also can become exacerbated if the electronic apparatus is supported in vertically stacked equipment racks. The lower electronic devices generate heat which begins to elevate the ambient air temperature around the upper apparatus supported on the rack, which heated air can be drawn into the upper housings.

Most typically, prior art fan-cooled electronic equipment has employed the strategy of mounting one or more fans at one side of the housing and pulling air into the housing from a side opposite to the fan. The air pulled into the housing passes over the PCB and any components coupled or mounted thereto. No attempt is made to control airflow within the device housing, and generally, high and low heat-generating components are cooled with approximately the same rate of airflow. The cooling air will enter the housing at an air temperature which is lowest at the air intake port and increase as the air flows across the PCB to the fan and the air exhaust port. This is true even though the electronic device may have its highest heat-generating components proximate the air exhaust port. As would be expected, this heat dissipation strategy is becoming less and less effective as the heat being generated in such electronic equipment housings increases.

Relatively high heat-generating components can be easily identified, and within bounds, their location on a PCB, card or substrate can be tailored, controlled or at least known. Relatively lower heat-generating components and circuitry also advantageously can be air cooled, but the convection heat transfer load created within the component housing by such lower heat-generating components is much less.

The apparatus and method of the present invention have other features, advantages and objects which will be apparent from the accompanying drawing or are set forth in more detail in the following Detailed Description Of The Invention.

### SUMMARY OF THE INVENTION

The heat dissipation structure of the present invention is suitable for use in electrical and electronic equipment housings that are fan cooled and is particularly well adapted for use in preferentially cooling relatively high heat-generating electronic components which are electrically coupled to PCB's or electronic component-carrying cards or substrates. The structure comprises, briefly, a partition array positioned in the equipment housing and formed to preferentially direct the airflow in the housing produced by a fan across relatively high heat-generating electronic components. The airflow rate and volume is directed by the partition array to be higher as compared to airflow in the housing over relatively low heat-generating electronic components and circuitry. In the most preferred form, the partition array is formed to accelerate airflow to a maximum flow rate proximate and over the highest heat-generating components. The partition array can include at least one horn which causes incoming air to flow in a flow path over a high heat-generating component. In the most preferred embodiment, a horn is positioned on the downstream side of the heat-generating components so as to collect air after passing over the component and direct the collected air to an air exhaust outlet.

The method of cooling electronic components of the present invention is comprised, briefly, of the steps of locating the high heat-generating electronic components or circuitry on a PCB, card or component supporting substrate; directing airflow in the apparatus housing produced by a fan preferentially over the located high-heat generating components for increased heat transfer to the flowing air, and exhausting the directed air from the housing. The locating step can be accomplished by merely identifying the high heat-generating components and their locations or by positioning the electronic components in a desired position on the PCB, card or substrate. The directing step is preferably accomplished by preferentially directing the airflow over the component using a partition array or structure within the housing which preferentially causes airflow over high heat-generating electrical components in the housing. The directing step also preferably includes the step of accelerating the rate of airflow to a maximum rate proximate the high-heat generating components. Finally, the directing step can include an additional step of collecting air passing over the electronic component using a collection partition, such as a horn.

### BRIEF DESCRIPTION OF THE DRAWING

FIG. 1 is a schematic, top perspective view, partially broken away, of an electronic device showing an airflow directing partition array constructed in accordance with the present invention.

FIG. 2 is a schematic, top perspective view, partially broken away, of the electronic device of FIG. 1 prior to mounting of the device into a separate fan-containing housing suitable for rack-mounting of a plurality of electronic devices.

FIG. 3 is a schematic, top perspective view corresponding to FIG. 2 with one electronic device mounted in the fan-containing housing and a second electronic device inverted and about to be mounted in the fan-containing housing.

FIG. 4 is a schematic, enlarged, top perspective view of the fan-containing housing with both electronic device mounted in the fan-containing housing.

FIG. 5 is a schematic, side elevation view, in cross section, of four electronic devices mounted in a common fan-containing housing and showing airflow through the electronic device housings and the fan-containing housing.

### DETAILED DESCRIPTION OF THE INVENTION

Reference will now be made in detail to the preferred embodiment of the present invention, examples of which are illustrated in the accompanying drawings. While the invention will be described in connection with the preferred embodiments, it will be understood that the illustrated embodiments are not intended to limit the invention. On the contrary, the invention is intended to cover alternatives, modifications and equivalents, which may be included within the spirit and scope of the invention, as defined by the appended claims.

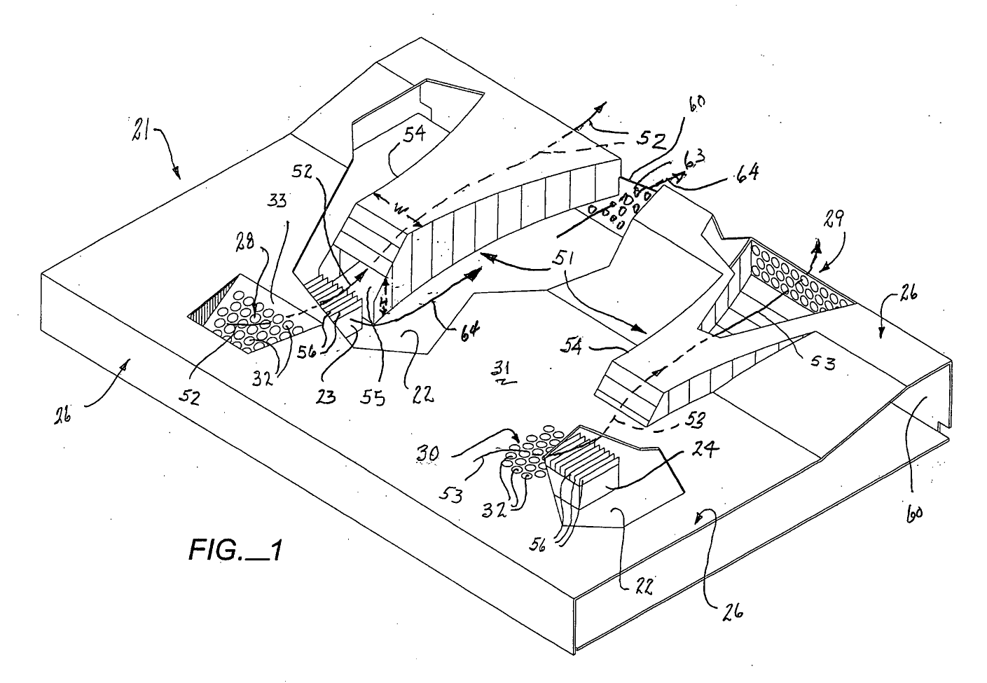

Turning now to FIG. 1, a schematic representation of an electrical or electronic device, generally designated 21, is shown. The function of device 21 is not critical to the present invention, but generally it will contain at least some components which tend to generate a relatively high thermal output, such as power transistors and/or data processors (e.g., CPUs), as well as related circuitry and components that tend to be relatively low sources of thermal energy. Both the high and low sources of thermal energy are typically mounted to a printed circuit board (“PCB”), card or substrate 22 inside a device housing 26.

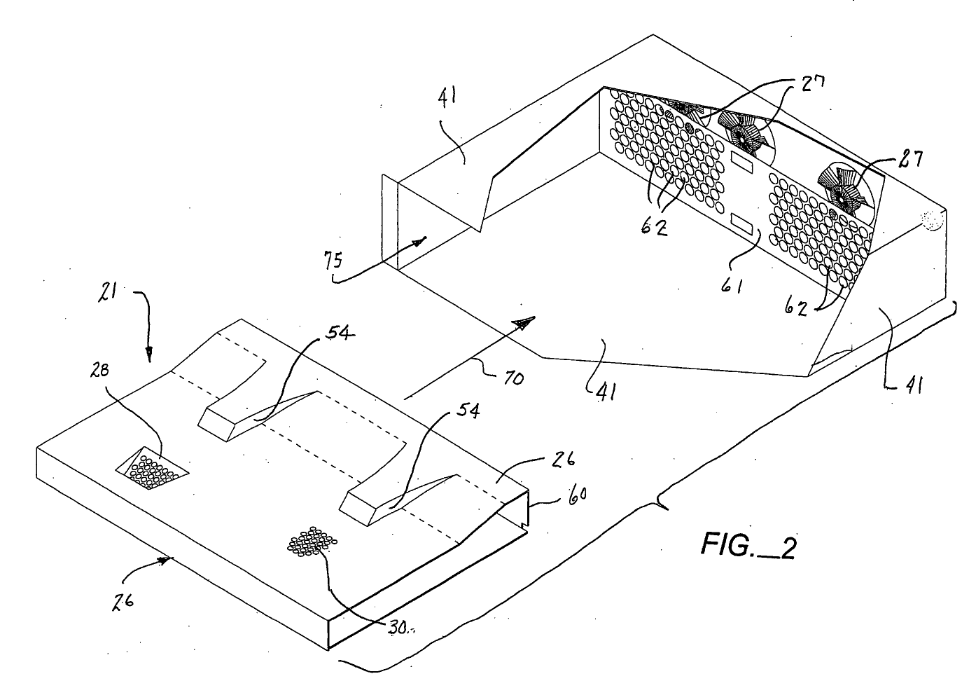

In FIG. 1, therefore, electronic device 21 includes a PCB 22 to which relatively high heat-generating electronic components 23 and 24 are mounted. The board and components are enclosed in a device housing 26, that is shown broken away for ease of understanding. Device 21 is air cooled by a fan or fans 27 (FIG. 2) which draw air into and through housing 26 over PCB 22 and components 23 and 24. Fans 27 are shown in FIG. 2 in a separate fan-containing housing 41, as will be described in greater detail below, but it will be understood to one skilled in the art that fans 27 also could be mounted in device housing 26.

Device housing 26 will typically have at least one air inlet opening 28 and at least one air outlet opening 29. As illustrated, device housing 26 has two inlet openings 28 and 30 in an upper surface 31 of housing 26. Inlets 28 and 30 can be provided as an array of perforations 32 which are formed in a downwardly tilted surface 33 for inlet 28 and which are provided in horizontal top surface 31 for inlet 30.

In the illustrated embodiment, fans 27 pull air into device housing 26 and across components 23 and 24, but it also will be understood that in some embodiments fans 27 can be immediately adjacent to the inlet openings and blow air across components 23 and 24 to air outlets 29 on the other side of the housing. The structure and method of the present invention can be used for either cooling approach.

As thus far described, the structure of electronic device 21 is well known.

In order to provide more efficient heat dissipation or transfer away from those electronic components which tend to be relatively high heat-generators, electronic device 21, in accordance with the present invention includes an airflow pathway defining partition array, generally designated 51. Partition array 51 is formed and positioned to define at least one pathway for airflow, as driven by fans 27, which directs the flowing air across or past relatively high heat-generating components 23 and 24 so that heat dissipation from such components is significantly improved as compared to the prior art approach of simply moving air in an unguided manner from one side of the device housing to the other. Such guided or preferential airflow past high heat-generating components results in cooling or heat transfer that can be better matched to heat generation. Rather than a random or indiscriminate airflow through housing 26, a preferential flow along guide paths 52 and 53 that are positioned within housing 26 so as to produce heat dissipation for the electronic components and circuitry which most need it. This approach makes a more efficient use of the power of fans 27 to move air and avoids cooling of components which really do not need to be cooled.

As a first step in designing the shape and position of airflow guiding partitions 51, therefore, the location of high heat-generating components 23 and 24 on board 22 needs to be determined. In a situation in which PCB boards and the components are laid out by one manufacturer and cooling partitions designed by another, it is simply a matter of locating the high-heat generating components on board 22 and designing partition array 51 to produce the most effective preferential airflow. More advantageously, however, the location or position of components 23 and 24 on board 22 can be designed to position the components on board 22 in a manner which accommodates efficient partition configurations within device housing 26. Thus, relatively high heat-generating components 23 and 24 are shown in FIG. 1 as being laterally separated with each component having a separate cooling airflow path.

In FIG. 1, two airflow paths, indicated by arrows 52 and 53, are shown with path 52 extending from inlet 28 to an outlet and path 53 extending from inlet 30 to outlet 29. In the illustrated partition array 51, both paths 52 and 53 are defined by horn-shaped partitions 54 that are positioned down-stream from components 23 and 24. Advantageously, but not necessarily, components 23 and 24 include heat transfer enhancing fins 56, which can be seen to be oriented to extend substantially parallel to flow paths 52 and 53 for improved heat transfer.

Moreover, as seen in FIG. 1, horns 54 have cross sectional areas which are narrowed proximate high heat-generating components 23 and 24. Thus, width dimension W, of horns 54 proximate horn mouth 55 and components 23 and 24 is less than the width proximate outlet ports 29. Moreover, horns 54 have a height dimension, H, which also is less close to mouth 55 and components 23 and 24 than it is at outlets 29. This construction causes airflow velocity to be increased in the area of the high heat-generating components for better heat transfer from components 23 and 24. It will be understood, however, that in the broadest concept of the invention partition array 51 does not need to accelerate air velocity; it only needs to preferentially channel airflow over the high heat-generating components to achieve substantial advantages.

As shown in FIG. 1, partition array 51 includes a horn 54 downstream of components 23 and 24. It is within the broad scope of the invention to provide a channel-defining partition or horn (not shown) between inlet ports 28, 30 and components 23 and 24. The partition also can take the form of a continuous tube having periodic cut-out portions up through which the high heat-generating components and/or fins 56 extend so as to be in the airflow path in the tube.

One of the advantages of not channeling all of the air drawn through device housing 26 is to provide at least some airflow outside paths 52 and 53 so that relatively low heat-generating components and circuitry also are cooled. In fact, it is one feature of the present invention that at least some of the airflow through device housing 26 be outside the preferential flow paths 52 and 53. This can be accomplished by forming fan-containing housing 41 with a perforated wall 61 with perforations 62 that extend laterally beyond outlets 29 in housing 26. End wall 60 of device housing 26 can be provided with perforations or openings 63 between outlets 29. Thus, most of the air pulled in through openings 28, 30 will be collected and directed by horns 54 in flow paths 52, 53, but some of the air also will be pulled through housing 26 along one or more auxiliary flow paths, as shown by arrows 64.

The quantity of air which flows in the primary flow paths 52, 53, as compared to auxiliary flow path 64, can be “tuned” by varying the area of openings 63. This also can be adjustable by providing a movable damper, not shown, which allows some of the openings 63 to be closed to effect tuning. In practice, this will usually be done once at the factory for a prototype of a given electronic device.

One will appreciate that the size of throat 55 of horns 54 also can be “tuned” or varied, alone or in combination with the areas of openings 63, to achieve the desired airflow volume between flow paths 52, 53 and 54, and accordingly, a better matching of heat transfer between high and low heat-generating components and circuitry.

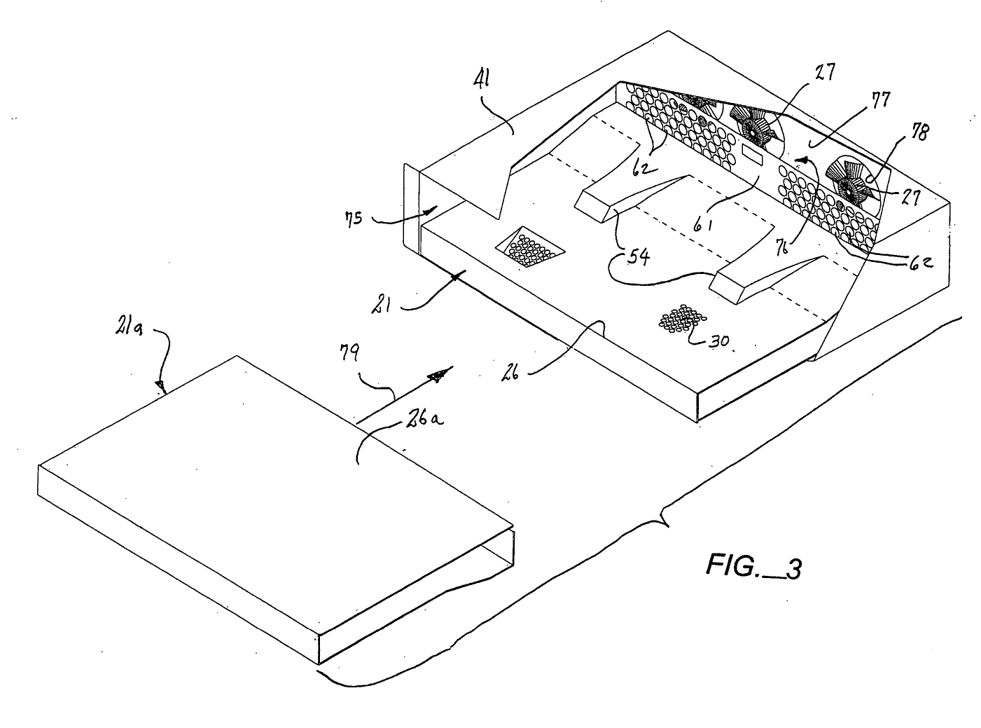

Referring now to FIG. 2, electronic device 21 can be seen immediately prior to its mounting inside fan-containing housing 41. As shown by arrow 70, device housing 26 will be inserted into opening 75 in housing 41 until the end wall 60 of housing 26 abuts perforated wall 61 of the fan-containing housing. FIG. 3 shows housing 26 as positioned in place inside fan-containing housing 21. As will be appreciated, this juxtaposes perforated outlet openings 29 next to the perforations 62 so that operation of the fans 27 will draw air through electronic device housing 26 along pathways 52, 53 and 54. Fans 27 are mounted in a chamber 76 behind perforated partition 61 and are driven by a motor. A rear wall 77 of housing 41 is provided with openings 78 for discharge of air by the fans outwardly of housing 41. The fans are schematically shown and would be mounted to a motor or motors which can be positioned in chamber 76 behind wall 61.

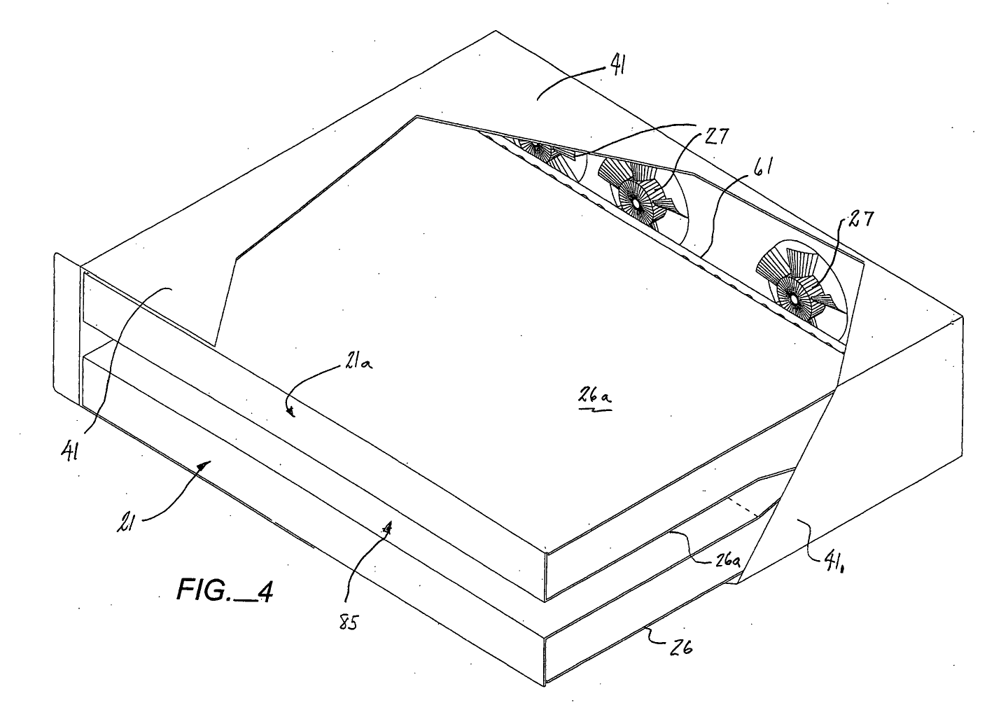

In FIG. 3, a second electronic device 21a having a housing 26a and a structure which is preferably substantially identical to that of electronic device 21 is shown outside the fan-containing housing 41. This second electronic device 26a will be moved into housing 41 as shown by arrow 79 in FIG. 3. Such a combined positioning of the two electronic devices 21, 21a is shown in FIG. 4. As will be seen in FIG. 4, the two electronic devices 21, 21a are vertically separated so as to define a slot 85 along the open front end of housing 41. The slot 85 allows air to enter fan-containing housing 21 between electronic devices 21, 21a so that the air can enter inlet ports 28 and 30 in each of the electronic device housings and be pulled through the housings along preferential flow paths past high heat-generating components inside the device housings 26, 26a.

The use of a common fan-containing housing 41 allows fans 27 to be of a somewhat larger size than would be the case if the fans were mounted inside device housings 26, 26a. The larger fans, and greater number of fans, will allow airflow through the device housings to be increased, which combines with the preferential directing of the airflow by the partition arrays 51 to further enhance heat dissipation.

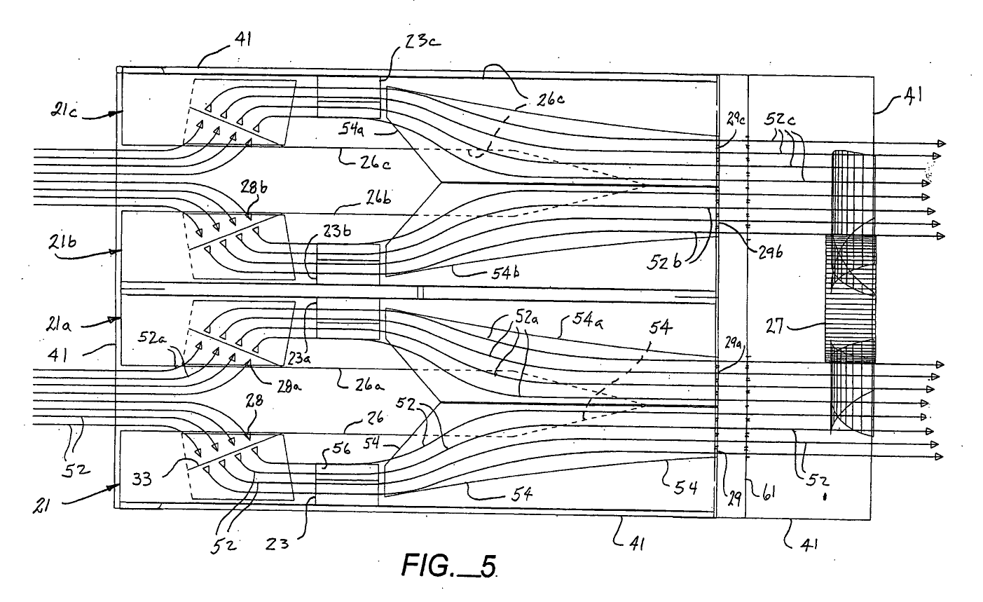

FIG. 5 shows airflow through a fan-containing housing 41 and four electronic device housings 26, 26a, 26b and 26c. Each electronic device 21, 21a, 21b and 21c is similarly formed, as shown and described in detail in connection with FIG. 1. The cross section in FIG. 5 is taken substantially in the plane of inlet opening 28 in which perforations 32 are formed in an inclined surface 33. The flow paths 52, 52a, 52b and 52c through device housings 26-26c are shown by arrows as the air flows into housing 26-26c and is drawn by horns 54, 54a, 54b and 54c past the high heat-generating components 23, 23a, 23b and 23c. Obviously, the array of FIG. 5 can be easily vertically replicated so that a large number of electronic/electrical devices 21 can be stacked in a vertically-extending assembly of the type typically supported on equipment racks.

Having described the apparatus of the present invention, the method can be set forth in more detail. A method of cooling electronic components includes the steps of locating the high heat-generating components and/or circuitry 23, 24 on the PCB, card or component supporting substrate 22; directing airflow in the device housing 26 produced by a fan 27 preferentially over the located high heat-generating components for increased heat dissipation or transfer to the air flowing over the components. The method also includes the step of exhausting the directed air from housing 26 of the electronic equipment. The locating step can be accomplished merely by identifying the high heat-generating components or circuitry and their locations on the PCB board. Most preferably, however, the board can be designed so as to position the components 23 and 24 in desirable locations for the purpose of preferentially controlling airflow using a partition array through the device housing 26. Thus, high heat-generating components can be aligned in a flow path 52, 53 or the flow of air along a path which is directed toward a plurality of such components, or they can be separated and a plurality of flow paths 52, 53 employed.

The step of directing the airflow is preferably accomplished using a partition array or structure within the housing that causes airflow over the high heat-generating electrical components. Most preferably, such airflow directing step includes the step of accelerating the rate of the airflow within the partition array to a maximum rate proximate the high heat-generating components.

Finally, the directing step also can include an additional step of collecting air passing over the electronic components using a collecting partition, such as a horn 54.

Numerous partition configurations can be employed to control airflow through the electronic device housing in a preferential manner which tends to match the airflow volume and rate to the demands for heat dissipation within the housing. Thus, the method can also be considered one of matching heat dissipation capacity to that of heat-generation capacity within the equipment housing.

Advantageously, the present invention allows for a heat dissipation structure and method for cooling electrical and electronic devices that can be tailored to match the localized heat transfer load created on PCB's, cards and substrates by heat-generating electrical components and circuitry.

Advantageously, the present invention allows for an airflow channeling partition structure suitable for use in an electronic equipment housing to preferentially direct airflow past high heat-generating electronic components inside the housing.

Advantageously, the present invention allows for a method of preferentially cooling higher heat-generating components in an electrical apparatus using a fan-driven air stream.

Advantageously, the present invention allows for a structure and method for enhanced cooling of electrical or electronic components in an enclosure. The structure is economical to construct and operate, is compact, can be adapted for use with a wide variety of housing and component configurations, is suitable for use with rack-mounted electronic devices, and is durable and easy to maintain.

The foregoing description of specific embodiments of the present invention has been presented for the purpose of illustration and description. They are not intended to be exhaustive or to limit the invention to precise forms disclosed and obviously many modifications and variations are possible in light of the above teaching. The embodiments were chosen and described in order to best explain the principles of the invention and its practical application as well as to enable others skilled in the art to best utilize the invention and the various embodiments with various modifications as are suited to the particular use contemplated.

What is claimed is:

1. A method of cooling electronic components having high heat-generating electronic components, the method comprising the steps of:
locating high heat-generating electronic components on a component supporting substrate;
directing airflow in the apparatus housing produced by a fan preferentially over the located high-heat generating components for increased heat transfer to the flowing air; and
exhausting the directed air from the apparatus housing.

2. The method of claim 1, wherein
the high heat-generating electronic components includes circuitry.

3. The method of claim 1, wherein
the component supporting substrate is one of a printed circuit board or a electronic component-carrying card.

4. The method of claim 1, wherein
the locating step is accomplished by identifying the high heat-generating components and their locations.

5. The method of claim 1, wherein
the locating step is accomplished by positioning the electronic components in a desired position on the component supporting substrate.

6. The method of claim 1, wherein
The directing step is accomplished by preferentially directing the airflow over the component using a structure within the apparatus housing which causes preferential airflow over high heat-generating electrical components in the apparatus housing.

7. The method of claim 6, wherein
the structure within the apparatus housing is a partition array.

8. The method of claim 1, wherein
the directing step includes the step of accelerating the rate of airflow to a maximum rate proximate the high-heat generating components.

9. The method of claim 8, wherein
the directing step further includes the step of collecting air passing over the electronic component using a collection partition.

10. The method of claim 8, wherein
the collection partition is a horn.

11. A heat dissipation structure for cooling heat-generating components in an electrical or electronic device having a housing and a cooling fan, the structure comprising:
a partition array positioned in the equipment housing dimensioned and configured to preferentially direct the airflow in the housing produced by the fan across relatively high heat-generating electronic components.

12. The structure of claim 11, wherein
wherein the partition array is dimensioned and configured to preferentially cool relatively high heat-generating electronic components which are electrically coupled to printed circuit boards, electronic component-carrying cards, and/or electronic component-carrying substrates.

13. The structure of claim 11, wherein
the airflow rate and volume produced by the fan is directed by the partition array to be higher over the relatively high heat-generating electronic components as compared to airflow in the housing over relatively low heat-generating electronic components.

14. The structure of claim 13, wherein
wherein the relatively low heat-generating electronic components include circuitry.

15. The structure of claim 11, wherein
the partition array is formed to accelerate airflow to a maximum flow rate proximate and over the highest heat-generating components.

16. The structure of claim 11, wherein
the partition array includes at least one horn dimensioned and configured to direct incoming air to flow in a flow path over a high heat-generating component.

17. The structure of claim 16, wherein
the at least one horn is positioned on a downstream side of the heat-generating components, wherein the at least one horn is dimensioned and configured to collect air after passing over the component and direct the collected air to an air exhaust outlet.
